(19) United States
(12) Patent Application Publication
(10) Pub. No.: US 2007/0109748 A1
(43) Pub. Date: May 17, 2007

(54) Adjusting device especially for a throttle valve of an internal combustion engine

(75) Inventor: Ralf Neise, Berlin (DE)

Correspondence Address: GRIFFIN & SZIPL, PC, SUITE PH-1, 2300 NINTH STREET, SOUTH, ARLINGTON, VA, 22204, US

(73) Assignee: PIERBURG GMBH, Neuss (DE)

(21) Appl. No.: 10/595,149

(22) PCT Filed: Aug. 24, 2004
(86) PCT No.: PCT/EP04/09424

§ 371 Date: Mar. 6, 2006

(30) Foreign Application Priority Data
Sep. 5, 2003 (DE) 103 41 394.4

(51) Int. Cl. H05K 7/20

(52) U.S. Cl. 361/715

(57) ABSTRACT

The invention relates to an adjusting device (1) which is characterized in that electrical contact is made by means of substantially exposed conductor tracks (12, 14) which are linked with a housing (9) of the adjusting device (1) merely in a positive fit. The conductor tracks (12, 14) are introduced by introducing a continuous perforation comb (13) and severing the webs (22) connecting the individual conductor tracks (12, 14) in an additional step. The inventive adjusting device is advantageous in that while having structurally identical housing components (9), it allows to replace the conductor tracks (12, 14) only or embody them differently, depending on how many contacts are required. It is therefore possible to adapt the conductor tracks to corresponding connector types or different position detecting devices without having to replace the entire board or housing (9) while ensuring an extremely reliable contacting.

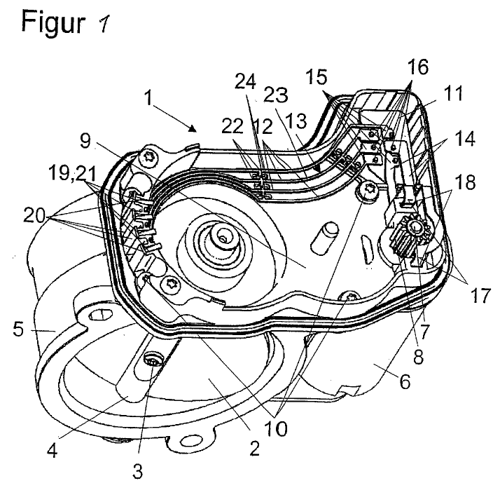

The invention relates to an adjusting device, in particular a valve adjusting device of a combustion engine, with an electric motor and a gear unit, which device is arranged in a housing that can be closed via a cover, whereby electrical conductor tracks are arranged in the housing to connect the connection contacts of the electric motor and a position detecting device to a plug of the adjusting device.

Adjusting devices in which a valve shaft with valves of an electric motor permanently arranged thereon are caused to rotate indirectly via a gear unit, are generally known, and are described in a number of patent applications. The electrical contacting between the connection contacts of the electric motor or of a position detecting device to a corresponding plug, whose embodiment varies according to the customer, is thereby realized in different ways.

While in the past movable cables were frequently soldered to the contact points, it has recently become the practice to realize the contacts via conductor tracks printed on a circuit board. Embodiments are also known in which the conductor tracks are printed directly onto a contact plate of a housing or of a cover of the adjusting device. Embodiments are likewise known in which the metallic conductor tracks are injected directly into the plastic or plastic is sprayed around the conductor tracks. From more recent use applications it is also known to make the conductor tracks from an electrically conductive plastic and to spray this plastic onto the circuit board or the housing, whereby this embodiment has the disadvantage that the contacting is not sufficiently reliable, in particular under a fairly high mechanical load, since the sprayed-on conductor tracks break.

However, all these forms of embodiment have the disadvantage that the complete boards or even housing components must be newly designed and manufactured for each new customer requirement with respect to the contacting, for example depending on how many connection contacts are necessary or what kind of position detecting device is used. The manufacturing must also be changed accordingly. The only exception is the freely movable cables that were used in earlier times, whereby such a connection is extremely difficult to carry out in today's limited installation space and results in increased production costs and assembly costs due to the individual solderings.

It is therefore the object of the invention to make available an adjusting device in which a structurally identical housing can be used for various customer requirements with respect to the use of different motors, connection contacts, and position detecting devices. Accordingly, if electronic malfunctions occur, a replacement of complete circuit boards or housing components is also to be avoided.

This object is achieved in that the electrical conductor tracks are embodied as metal stampings that can be connected to the housing with positive engagement, which stampings feature a defined shape, whereby the conductor tracks with the plug can be replaced. The contacting between the electric motor or the position detecting device and the plug is embodied such that it is possible to replace or add only the conductor tracks with the plug component but without additional housing components. The basic structural shapes of the housing on or to which the conductor tracks are fixed, can also be retained for different necessary contactings and plug embodiments based on different customer wishes, for example different position detecting devices, without having to change the shapes and thus the tools for the production of the housing. Thus a high flexibility arises in the connection of the electrical attachments.

In a preferred form of embodiment, the conductor tracks are embodied as a perforation comb, whereby the individual conductor tracks are connected via bridges, which connection can be severed through a stamping process after the perforation comb has been placed in the housing. This has the advantage that the entire electrical connection can be replaced as one component and thus is simple to produce and above all to mount. The housing component into which the perforation comb is placed is embodied thereby such that corresponding recesses are arranged in the area of the bridges, in which recesses a tool can engage in order to sever the individual conductor tracks.

In a preferred form of embodiment the respective first ends of the conductor tracks lead to the plug, in which they lock with stamped-out locking projections or are coated with sprayed plastic. Thus a reliable contacting is formed in a simple manner and simultaneously the plug component arranged in the housing is sealed against the outside atmosphere, whereby the plug can be embodied in one piece with the housing as well as able to be separated from one another, i.e. in two pieces.

In an alternative form of embodiment the respective first ends of the conductor tracks lead to the plug, where an electrical contact to pins of the plug can be produced via a press connection. Thus the plug component can be manufactured individually and only be connected to the conductor tracks via this press connection in a subsequent assembly step.

It is likewise advantageous if the respective second ends of the conductor tracks producing the contact to the motor are plugged into receptacle pockets of the housing, where they produce a frictional connection to connecting lugs of the electric motor. By these means the necessary connection can be produced during the assembly by simply plugging-in the electric motor and the conductor track without additional production or assembly steps, as a result of which assembly costs are reduced.

Moreover the respective second ends of the conductor tracks producing the contact to the position detecting device are advantageously shaped in such a way that a connection to the connection contacts of the position detecting device can be produced by bracing the second ends of the conductor tracks against a structural component of the position detecting device.

In a particular embodiment the position detecting device can be a potentiometer, whereby the respective second ends of the conductor tracks producing the contact to the potentiometer are shaped in such a way that a connection to the arm tracks of the potentiometer can be produced by bracing the end pieces of the second ends of the conductor tracks against a potentiometer circuit board. The potentiometer circuit board can thereby be embodied either in one piece with the housing cover or in the housing itself or can be connected to the housing as an individual structural component. In all cases a simple contacting results without additional assembly steps.

In a preferred form of embodiment the conductor tracks are fixed to the housing with positive engagement in the area of their respective ends and their bridges, so that an axial displacement of the conductor tracks is prevented.

In a further form of embodiment, the bridges of the perforation combs engage in recesses on the housing in such a way that the positive engagement connection is produced. By these means both the severing of the individual conductor tracks from one another and their fixing to the housing can take place in only one operational step, so that assembly steps can be saved.

In an alternative embodiment, the positive engagement connection takes place through the hot caulking of projections of the contact plate on the conductor tracks.

In a further alternative form of embodiment, a sealing adhesive is applied at at least one position of the conductor tracks and/or in the area of the connection between the pins of the plug and the conductor tracks, by which means the fixing of the conductor tracks on the plug or on the housing is again realized in a simple manner.

An adjusting device is thus created with which the contacting is reliably ensured in a housing of an adjusting device, and a high flexibility is thereby achieved with respect to the number or the position of the conductor tracks as well as with respect to the connection to a customer-requested plug. By these means the number of identical structural components of the adjusting device can be increased so that further costs can be saved. A replacement of the electrical contacting is possible, without having to replace other parts at the same time.

An adjusting device according to the invention is shown in the drawing and is described below.

The FIGURE shows in a three-dimensional representation, an opened housing of an adjusting device according to the invention, using a throttle valve adjusting device as an example.

The adjusting device 1 shown in the FIGURE is used here by way of example for the adjustment of a throttle valve 2 that is fixed on a shaft 4 via screws 3 and that is arranged in a throttle valve housing 5. The adjusting device 1 comprises an electric motor 6 on whose motor shaft 7 a gear wheel 8 is arranged that drives the throttle valve shaft 4 via a further reduction gear, not shown. The gear, the electrical contacting, and if applicable the electric motor, are arranged in a housing 9 that is fixed to the throttle valve housing 5 via screws 10 and is closed by means of a cover, not shown.

The electrical contacting of a plug 11 to a position detecting device, not shown in greater detail, takes place via stamped conductor tracks 12, which can be introduced into the housing 9 adhering as a perforation comb 13. The contacting of the plug 11 to the connecting lugs, not shown, of the electric motor 6 takes place via further stamped conductor tracks 14.

Respective first ends 15 of the conductor tracks 12, 14 are connected via a press connection to pins 16 of the plug 11 that exit from the housing 9 on the opposite side of the housing 9. For the additional reliability and sealing of this connection, a sealing adhesive can be applied in the area of the plug 11. It would also be conceivable to embody the conductor tracks 12, 14 so that their first ends 15 are respectively bent by 90 degrees and pass through the housing via locking projections and thus simultaneously serve as pins 16 of the plug 11, whereby in such an embodiment a sealing between the housing 9 and the pins 16 or first ends 15 of the conductor tracks 12, 14, would have to be guaranteed.

Second ends 17 of the conductor tracks 14 for the contacting of the electric motor 6 are finally shaped so that they point in the axial direction and there engage in receptacle pockets 18, where a frictional connection to connection contacts, not shown, of the electric motor 6 is produced by pushing the ends 17 into the receptacle pockets 18. This is guaranteed in that the second ends 17 lie in a springy manner adjacent to one side of the receptacle pockets 18, on which the motor connection contacts also lie, so that the contact to the connecting lugs of the motor 6 by frictional connection is ensured. The second ends 19 shown, of the conductor tracks 12, are embodied for the contacting of arm tracks, not shown, of a potentiometer, not shown, in such a way that the conductor tracks 12 otherwise running transverse to the axial direction are first bent in this area 19 by 90 degrees, whereby this part is arranged in receptacle pockets 20, and then are bent again by an angle smaller than 90 degrees. These end pieces 21 extend from the receptacle pockets 19 in such a way that these end pieces 21 can be deformed in the axial direction. During the subsequent mounting of a potentiometer circuit board with arm tracks arranged thereon, which is not shown, the board is pressed onto the end pieces 21 so that the pieces can be bent in a springy manner in the direction of the throttle valve, so that a frictional connection is produced to the arm tracks of the potentiometer.

As mentioned, the conductor tracks 12 are embodied as a perforation comb 13, whereby bridges 22 are arranged between the individual conductor tracks. If necessary, these bridges 22 can be used to fix the center sections 23 of the conductor tracks 12, in that when the bridges 22 are severed, they can be bent until they engage in corresponding recesses 24 of the housing 9, so that a positive engagement connection results between the housing 9 and the conductor tracks 12. This takes place in particular when the fixing by means of the connection to the plug or by means of the acceptance of the conductor track ends 19 in the receptacle pockets 20 is not sufficient for the axial fixing of the conductor tracks 12 essentially running transverse to the axial direction.

An alternative possible method for fixing the center sections 23 of the conductor tracks 12, 14 can take place in that projections, not shown, embodied on the housing 9 by means of hot caulking are pressed onto the conductor tracks 12, 14. Adhering with the aid of a sealing adhesive is also conceivable.

This form of embodiment shows that the contacting via conductor tracks that essentially lie exposed in the housing can take place in a simple manner, whereby assembly steps are saved by means of the frictional connections, but the conductor tracks are nonetheless fixed in the housing and can be replaced independently of the housing. In comparison with known embodiments, the assembly cost does not increase, since all the conductor tracks are embodied jointly as a perforation comb and can be introduced into the housing.

1. An adjusting device, for a valve drive of a combustion engine, comprising:
an electric motor; and
a gear unit connected to the electric motor, wherein the adjusting device is arranged in a housing that can be closed via a cover, whereby electrical conductor tracks are arranged in the housing to connect connection contacts of the electric motor and a position detecting device to a plug of the adjusting device,
wherein the electrical conductor tracks include first conductor tracks and second conductor tracks comprising metal stampings that are connectable to the housing with positive engagement, and these stampings have a defined shape, whereby the conductor tracks are replaceable with the plug.

2. An adjusting device according to claim 1, wherein the electrical conductor tracks further comprise a perforation comb, and individual conductor tracks are connected via bridges, wherein each connection can be severed through a stamping process after the perforation comb has been placed in the housing.

3. An adjusting device according to claim 1, wherein respective first ends of the electrical conductor tracks lead to the plug, in which the electrical conductor tracks lock with stamped-out locking projections or are coated with sprayed plastic.

4. An adjusting device according to claims 1, wherein respective first ends of the electrical conductor tracks lead to the plug and an electrical contact to pins of the plug is provided via a press connection.

5. A adjusting device according to claims 1, wherein in that respective second ends of the first conductor tracks providing producing the contact to the motors are plugged into receptacle pockets of the housing, where the respective second ends provide a frictional connection to connecting lugs of the electric motor.

6. An adjusting device according claims 1, wherein respective second ends of the second conductor tracks provide contact to the position detecting device and are shaped so that a connection to the connection contacts of the position detecting device is provided by bracing the second ends of the second conductor tracks against a structural component of the position detecting device.

7. An adjusting device according to claim 6, wherein the position detecting device is a potentiometer, and the respective second ends of the second conductor tracks providing contact to the potentiometer are shaped so that a connection to arm tracks of the potentiometer is produced by bracing end pieces of the second ends of the second conductor tracks against a potentiometer circuit board.

8. A adjusting device according to claim 2, wherein the electrical conductor tracks are fixed to the housings with positive engagement in the area of respective ends of the electrical conductor tracks and corresponding bridges.

9. Adjusting device according to claim 8, wherein bridges of the perforation combs engage in recesses on the housings so as to provide positive engagement connection.

10. An adjusting device according to claim 1, wherein the positive engagement connection takes place through hot caulking of projections of the housings on the electrical conductor tracks.

11. An adjusting device according to claim 1, wherein a sealing adhesive is applied at at least one position of
i. the electrical conductor tracks,
ii. in the area of the connection between the pins of the plug and the electrical conductor tracks, or
iii. the electrical conductor tracks and in the area of the connection between the pins of the plug and the electrical conductor tracks.

12. An adjusting device according to claim 2, wherein respective first ends of the electrical conductor tracks lead to the plug in which the electrical conductor tracks lock with stamped-out locking projections or are coated with sprayed plastic.

13. An adjusting device according to claim 2, wherein respective first ends of the electrical conductor tracks lead to the plug and an electrical contact to pins of the plug is provided via a press connection.

14. An adjusting device according to claim 1, wherein a sealing adhesive is applied at at least one position of the electrical conductor tracks.

15. An adjusting device according to claim 1, wherein a sealing adhesive is applied at at least one position of in the area of the connection between the pins of the plug and the electrical conductor tracks.

16. An adjusting device according to claim 1, wherein a sealing adhesive is applied at at least one position of the electrical conductor tracks and in the area of the connection between the pins of the plug and the electrical conductor tracks.
